(19) United States
(12) Patent Application Publication
(10) Pub. No.: US 2016/0284747 A1
(43) Pub. Date: Sep. 29, 2016

(54) 4-COLOR IMAGE SENSOR AND METHOD FOR FABRICATING THE SAME

(71) Applicant: SILICONFILE TECHNOLOGIES INC., Gyeonggi-do (KR)

(72) Inventors: Jae Young PARK, Gyeonggi-do (KR); Won Ho LEE, Gyeonggi-do (KR)

(21) Appl. No.: 15/079,835

(22) Filed: Mar. 24, 2016

(30) Foreign Application Priority Data
Mar. 24, 2015 (KR) 10-2015-0041031

(51) Int. Cl. H01L 27/146

(52) U.S. Cl. CPC H01L 27/14605; H01L 27/14645; H01L 27/14689

(57) ABSTRACT

A 4-color image sensor may include a first unit pixel region having Gr, R, IR and B pixels on four divided regions; and a second unit pixel region having IR, R, Gb and B pixels on four divided regions, wherein the first unit pixel region and the second unit pixel regions are alternately arranged in a vertical direction and a horizontal direction, and the IR pixel is consecutively arranged along a diagonal line direction.

### CROSS-REFERENCE TO RELATED APPLICATIONS

The present application claims priority of Korean Patent Application No. 10-2015-0041031, filed on Mar. 24, 2015, which is incorporated herein by reference in its entirety.

### BACKGROUND

1. Field

Exemplary embodiments of the present invention relate to a 4-color image sensor and a method for fabricating the same that prevents a resolution of an image sensor from being degraded, and more particularly, a 4-color image sensor and a method for fabricating the same that prevents a resolution of an image sensor from being degraded when the 4-color image sensor having a red, green and blue-infrared ray (RGB-IR) pixel is implemented.

2. Description of the Related Art

An image sensor using a red, green and blue (RGB) pixel senses a 3-color image of a visible ray region through a plurality of 3-color unit pixel regions, namely, a plurality of regions composed of red color (R), green color (G) and blue color (B) pixels. Each of the R, G and B pixels includes a plurality of transistors, capacitors and photodiodes, and outputs an electrical signal corresponding to a photo signal.

FIG. 1 illustrates a pixel scheme of an image sensor using a conventional RGB pixel. As shown in FIG. 1, a plurality of unit pixel regions 110 are sequentially arranged in a vertical direction and a horizontal direction. Each of the plurality of unit pixel regions 110 includes R, Gr, Gb and B pixels. The Gr, R, Gb and B pixels are sequentially arranged in a quadrant along a clockwise direction. That is, the Gr, R, Gb and B pixels are symmetrically arranged in an up/down direction and a left/right direction, respectively.

An image sensor using an RGB-IR pixel senses a 3-color image of a visible ray region through a plurality of 4-color unit pixel regions, namely, a plurality of pixel regions composed of R, Gr, B and IR, and senses an infrared image through the IR pixel. Herein, the Gr pixel denotes the G pixel neighbored with the R pixel in a horizontal direction, and the Gb pixel denotes the G pixel neighbored with the B pixel in a horizontal direction. Each of the R, G, B and IR pixels includes a plurality of transistors, capacitors and photodiodes, and outputs an electrical signal corresponding to the photo signal.

FIG. 2 illustrates a pixel scheme of an image sensor using a conventional RGB-IR pixel. As shown in FIG. 2, a plurality of unit pixel regions 210 are sequentially arranged in a vertical direction and a horizontal direction. Each of the plurality of unit pixel regions 110 includes R, Gr, B and IR pixels. The Gr, R, IR and B pixels are sequentially arranged in a quadrant along a clockwise direction. That is, the Gr, R, IR and B pixels are symmetrically arranged in an up/down direction and a left/right direction respectively.

As described above, since the Gb pixel of the image sensor using the conventional RGB pixel is replaced with the IR pixel in the image sensor using the conventional RGB-IR pixel, the G image is not read at every column and row in the image sensor using the conventional RGB-IR pixel, and the G image and the IR image are read once every two lines, and thereby the resolution of the image sensor is degraded.

### SUMMARY

Various embodiments of the present invention are directed to a 4-color image sensor having IR pixel that is arranged to prevent a resolution of G pixel and IR pixel from being degraded by raising a spatial frequency of an IR pixel and a G pixel when an IR pixel is arranged instead of a Gb pixel or a Gr pixel of a 3-color image sensor in order to implement a 4-color image sensor having an RGB-IR pixel.

Various embodiments of the present invention are directed to a method for fabricating a 4-color image sensor having R pixel that is arranged to prevent a resolution of G pixel and IR pixel from being degraded by raising a spatial frequency of an IR pixel and a G pixel when an IR pixel is arranged instead of a Gb pixel or a Gr pixel of a 3-color image sensor.

In accordance with an embodiment of the present invention, a 4-color image sensor may include a first unit pixel region having Gr R, IR and B pixels on four divided regions; and a second unit pixel region having IR, R, Gb and B pixels on four divided regions, wherein the first unit pixel region and the second unit pixel regions may be alternately arranged in a vertical direction and a horizontal direction, and the IR pixel may be continuously arranged along a diagonal line direction.

The Gr, R, IR and B pixels may be sequentially arranged in the four divided regions of the first unit pixel region along a clockwise direction, and the IR, R, Gb and B pixels may be sequentially arranged in the four divided regions of the second unit pixel region along the clockwise direction.

The Gr pixel and the Gb pixel may be set to have a high gain value compared to other pixels.

The diagonal line direction may be one of a diagonal line along a right and upward direction and a diagonal line along a left and upward direction.

In accordance with another embodiment of the present invention a 4-color image sensor may include a first unit pixel region having Gr, R, IR and B pixels on four divided regions; and a third unit pixel region having Gr, R, Gb and B pixels on four divided regions, wherein the first unit pixel region and the third unit pixel regions may be alternately arranged in a vertical direction and a horizontal direction, and IR pixel may be discontinuously arranged along a diagonal line direction.

In accordance with another embodiment of the present invention, a 4-color image sensor may include a third unit pixel region having Gr, R, Gb and B pixels on four divided regions; and a second unit pixel region having IR, R, Gb and B pixels on four divided regions; and wherein the third unit pixel region and the second unit pixel regions may be alternately arranged in a vertical direction and a horizontal direction, and the IR pixel may be discontinuously arranged along a diagonal line direction.

The diagonal line direction may be one of a diagonal line along a right and upward direction and a diagonal line along a left and upward direction.

In accordance with another embodiment of the present invention, a method for fabricating a 4-color image sensor may include defining a first unit pixel region to arrange Gr, R, IR and B pixels on four divided regions; defining a second unit pixel region to arrange IR, R, Gb and B pixels on four divided regions; defining the first unit pixel region and the second unit pixel region to be alternately arranged in a whole pixel region at odd number-th rows; defining the second unit pixel region and the first unit pixel region to be alternately arranged in the whole pixel region at even number-th rows; and forming the whole pixel region where the first unit pixel region and the second unit pixel region are defined.

In accordance with another embodiment of the present invention, a method for fabricating a 4-color image sensor may include defining a first unit pixel region to arrange Gr, R, IR and B pixels on four divided regions; defining a third unit pixel region to arrange Gr, R, Gb and B pixels on four divided regions; defining the first unit pixel region and the third unit pixel region to be alternately arranged in a whole pixel region at odd number-th rows; defining the third unit pixel region and the first unit pixel region to be alternately arranged in the whole pixel region at even number-th rows; and forming the whole pixel region where the first unit pixel region and the third unit pixel region are defined.

In accordance with another embodiment of the present invention, a method for fabricating a 4-color image sensor may include defining a third unit pixel region to arrange Gr, R, Gb and B pixels on four divided regions; defining a second unit pixel region to arrange IR, R, Gb and B pixels on four divided regions defining the third unit pixel region and the second unit pixel region to be alternately arranged in a whole pixel region at odd number-th rows; defining the second unit pixel region and the third unit pixel region to be alternately arranged in the whole pixel region at even number-th rows; and forming the whole pixel region where the third unit pixel region and the second unit pixel region are defined.

In accordance with another embodiment of the present invention, a 4-color image sensor may include a unit pixel region definition unit including a first unit pixel region definition u nit suitable for defining Gr, R, IR and B pixel regions to be arranged on four divided regions; a second unit pixel region definition unit suitable for defining the IR, R, Gb and B pixel regions to be arranged on four divided regions; and a third unit pixel region definition unit suitable for defining the Gr, R, Gb and B pixel regions to be arranged on four divided regions, a whole pixel region definition unit suitable for defining two unit pixel regions among three unit pixel regions, which are defined by the first to third unit pixel definition units, to be alternately arranged in a vertical direction and a horizontal direction; and an image sensor generation unit suitable for forming the whole pixel region, which is defined by the whole pixel region definition unit.

### BRIEF DESCRIPTION OF THE DRAWINGS

FIG. 1 illustrates a pixel scheme of an image sensor using a conventional RGB pixel.

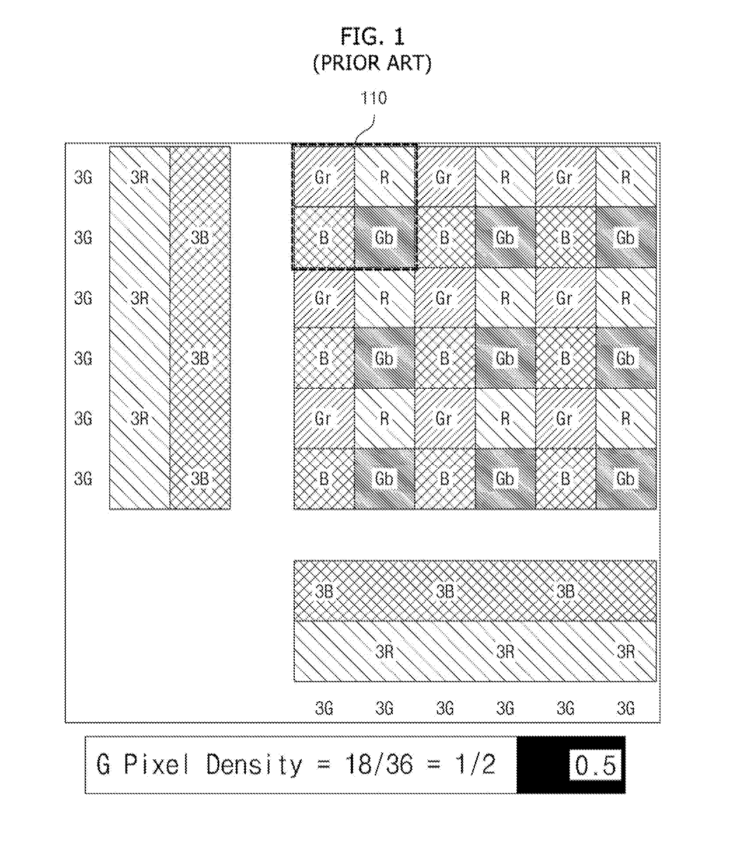

FIG. 2 illustrates a pixel scheme of an image sensor using a conventional RGB-IR pixel.

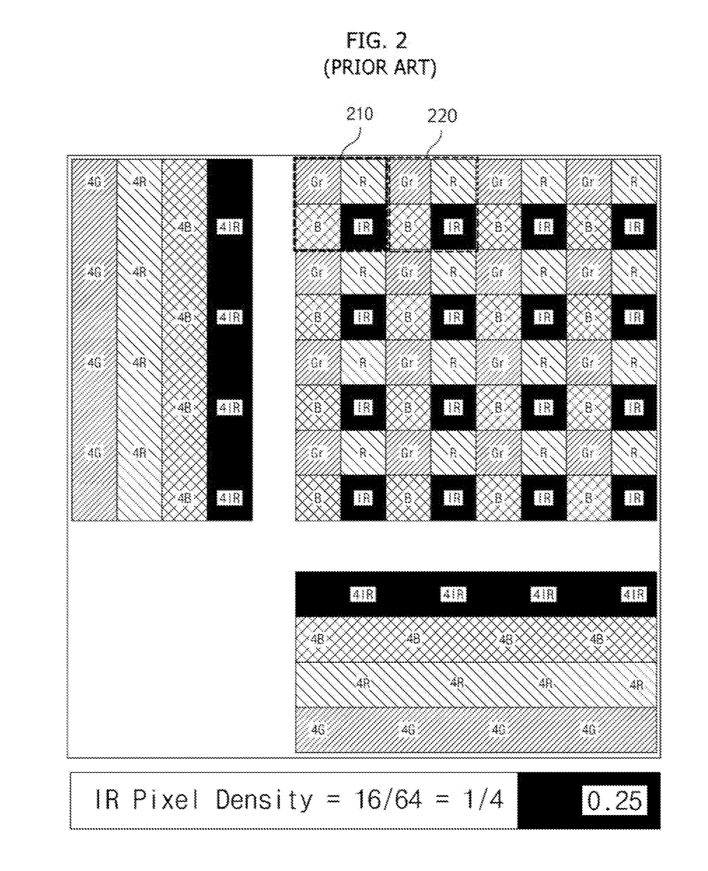

FIG. 3A illustrates a pixel arrangement of a 4-color image sensor in accordance with a first embodiment of the present invention.

FIG. 3B illustrates a pixel arrangement of a 4-color image sensor in accordance with a second embodiment of the present invention.

FIG. 3C illustrates a pixel arrangement of a 4-color image sensor in accordance with a third embodiment of the present invention.

FIG. 4A is a flow chart illustrating a method for fabricating a 4-color image sensor shown in FIG. 3A in accordance with a first embodiment of the present invention.

FIG. 4B is a flow chart illustrating a method for fabricating a 4-color image sensor shown in FIG. 3B in accordance with a second embodiment of the present invention.

FIG. 4C is a flow chart illustrating a method for fabricating a 4-color image sensor shown in FIG. 3C in accordance with a first embodiment of the present invention.

FIG. 5 is a block diagram illustrating a configuration of a 4-color image sensor in accordance with embodiments of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

Throughout the specification, when an element is referred to as being “coupled” to another element, it may not only indicate that the elements are “directly coupled” to each other, but also indicate that the elements are “electrically coupled” to each other with another element interposed therebetween. Furthermore, when one element is referred to as “including” or “having” some elements, it should be understood that it may include or have only those elements, or it may include or have other elements as well as those elements if there is no specific limitation. The terms of a singular form may include plural forms unless referred to the contrary.

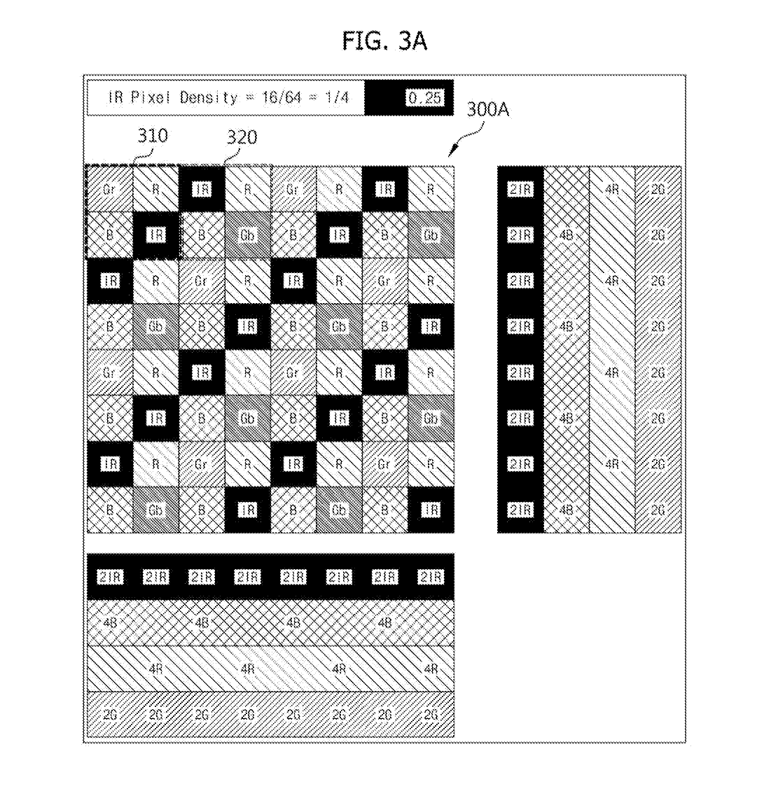

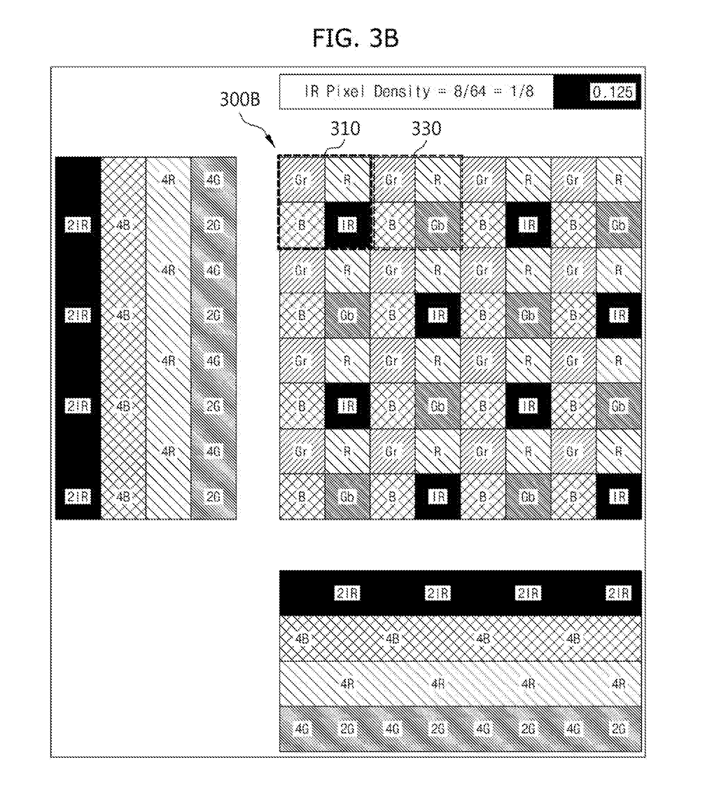

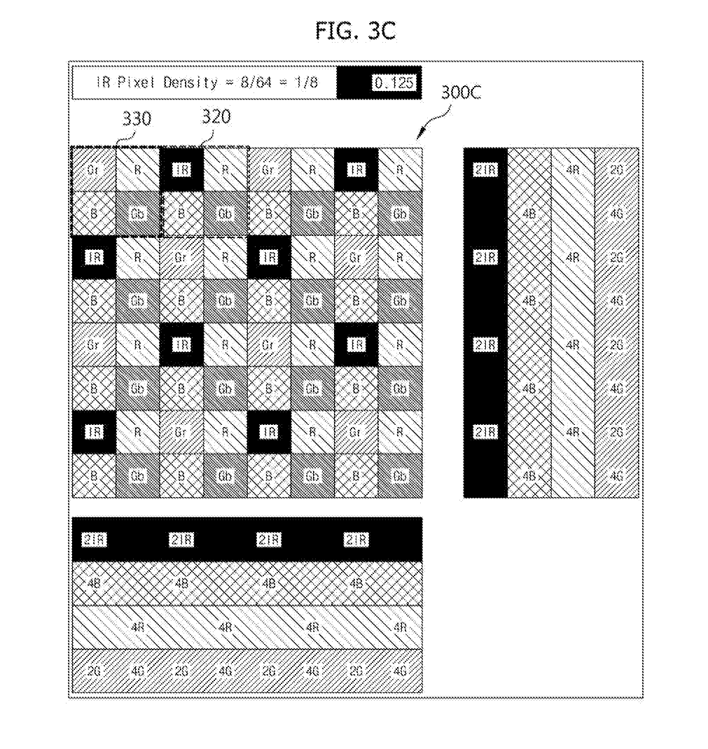

FIG. 3A illustrates a pixel arrangement of a 4-color image sensor in accordance with a first embodiment of the present invention.

As shown in FIG. 3A, a first unit pixel region 310 is defined by sequentially arranging Gr, R, IR and B pixels on four divided regions, which are symmetrically arranged in a vertical direction and a horizontal direction, along a clockwise direction.

A second unit pixel region 320 is defined by sequentially arranging IR, R, Gb and B pixels on four divided regions, which are symmetrically arranged in a vertical direction and a horizontal direction, along the clockwise direction.

The first unit pixel region 310 and the second unit pixel region 320 are defined to be alternately arranged at every odd number-th row of the whole pixel region 300A.

Likewise, the second unit pixel region 320 and the first unit pixel region 310 are defined to be alternately arranged at every even number-th row of the whole pixel region 300A.

Afterwards, a 4-color image sensor including a scheme as shown in FIG. 3A is manufactured by performing a processes for forming the whole pixel region 300A, which is defined as described above.

In conclusion, as shown in FIG. 3, case that unit pixel regions are defined in the whole pixel region 300A along a row direction and a column direction, the first unit pixel region 310 having the IR pixel instead of the Gb pixel and the second unit pixel region 320 having the IR pixel instead of the Gr pixel are defined to be alternately arranged at the odd number-th rows, and the second unit pixel region 320 and the first unit pixel region 310 are defined to be alternately arranged at even number-th rows.

The image sensor having the above-described scheme may sense an infrared image and a color image of a visible ray region. Herein, the Gr pixel denotes the G pixel neighbored with the R pixel in a horizontal direction, and the Gb pixel denotes the G pixel neighbored with the B pixel in a horizontal direction. Each of the R, G, B and IR pixels includes a plurality of transistors, capacitors and photodiodes, and outputs an electrical signal corresponding to a photo signal.

A spatial frequency of the IR pixel and the G pixel is improved to two times as compared to a conventional image sensor by defining the arrangement of the IR pixels as shown in FIG. 3. Thus, even if 4-color pixel is used, the degradation of the resolution of G color and IR color is minimized by sensing the G color and the IR color once at every one line.

In case that the IR pixel is defined as described above, the density of the G color is degraded, the sensitivity of the image sensor may be degraded. This problem may be resolved by setting a digital gain having a high value to the G pixel during an image sensor design process. That is, the problem that the density of the G color is lowered and the sensitivity of the image sensor is degraded may be resolved by appropriately adjusting an analog and digital gain on the G pixel when a setting value of each of pixels is adjusted to optimize the characteristics of pixels.

In FIG. 3A, the IR pixel region is exemplarily illustrated to be arranged in a diagonal line along a right and upward direction, but the embodiment of the present invention is not limited to this.

For example, in another embodiment of the present invention, the IR pixel region may be arranged in a diagonal line along a left and upward direction. That is, the first unit pixel region may be defined by sequentially arranging Gr, R, IR and B pixels on four divided regions, which are symmetrically arranged in a vertical direction and a horizontal direction, along a counter clockwise direction. A second unit pixel region may be defined by sequentially arranging. IR, R, Gb and B pixels on four divided regions, which are symmetrically arranged in a vertical direction and a horizontal direction, along a counter clockwise direction. When the first unit pixel region and the second unit pixel region are defined, if corresponding pixels are defined to be arranged along from right to left, the IR pixels may be arranged in a diagonal line along the left and upward direction.

For reference, as shown in FIG. 3A, in case that the IR pixels are alternately arranged in the whole pixel regions 300A along a diagonal line direction, a function of a conventional dead pixel concealment (DPC) may be not used.

FIG. 3B illustrates a pixel arrangement of a 4-color image sensor in accordance with a second embodiment of the present invention, in order to solve the non-use of the DPC.

As shown in FIG. 3B, a first unit pixel region 310 is defined by sequentially arranging Gr, R, IR and B pixels on four divided regions, which are symmetrically arranged in a vertical direction and a horizontal direction, along a clockwise direction.

A third unit pixel region 330 is defined by sequentially arranging Gr, R, Gb and B pixels on four divided regions, which are symmetrically arranged in a vertical direction and a horizontal direction, along the clockwise direction.

The first unit pixel region 310 and the third unit pixel region 330 are defined to be alternately arranged at every odd number-th row of the whole pixel region 3006.

Likewise, the third unit pixel region 330 and the first unit pixel region 310 are defined to be alternately arranged at every even number-th row of the whole pixel region 300B.

Afterwards, a 4-color image sensor including a scheme as shown in FIG. 36 is manufactured by performing a processes for forming the whole pixel region 300B, which is defined as described above.

In conclusion, as shown in FIG. 36, in case that unit pixel regions are defined in the whole pixel region 300B along a row direction and a column direction, the first unit pixel region 310 having the IR pixel instead of the Gb pixel and the third unit pixel region 330 excluding IR pixel are defined to be alternately arranged at the odd number-th rows and the third unit pixel region 330 and the first unit pixel region 310 are defined to be alternately arranged at even number-th rows.

The image sensor having the above-described scheme may sense an infrared image and a color image of a visible ray region. Herein, the Gr pixel denotes the G pixel neighbored with the R pixel in a horizontal direction, and the Gb pixel denotes the G pixel neighbored with the B pixel in a horizontal direction. Each of the R, G, B and IR pixels includes a plurality of transistors, capacitors and photodiodes, and outputs an electrical signal corresponding to a photo signal.

By defining the arrangement of the IR pixels as shown in FIG. 3B, the IR color has a same resolution compared to a conventional 4-color image sensor and a spatial frequency of the G pixel is improved to two times compared to a conventional 4-color image sensor by defining the arrangement of the IR pixels as shown in FIG. 3. Thus, a function of a conventional DPC may be used.

In FIG. 3B, the IR pixel region is exemplarily illustrated to be arranged in a diagonal line along a right and upward direction, but the embodiment of the present invention is not limited to this.

For example, in another embodiment of the present invention, the IR pixel region may be arranged in a diagonal line along a left and upward direction. That is, the first unit pixel region may be defined by sequentially arranging Gr, R, IR and B pixels on four divided regions, which are symmetrically arranged in a vertical direction and a horizontal direction, along a counter clockwise direction. A third unit pixel region may be defined by sequentially arranging Gr, R, Gb and B pixels on four divided regions, which are symmetrically arranged in a vertical direction and a horizontal direction, along a counter clockwise direction. When the first unit pixel region and the third unit pixel region are defined, the IR pixels may be arranged in a diagonal line along the left and upward direction if corresponding pixels are defined to be arranged along from right to left.

FIG. 3C illustrates a pixel arrangement of a 4-color image sensor in accordance with a third embodiment of the present invention, in order to solve the non-use of the DPC.

As shown in FIG. 3C, a third unit pixel region 330 is defined by sequentially arranging Gr, R, Gb and B pixels on four divided regions, which are symmetrically arranged in a vertical direction and a horizontal direction, along the clockwise direction.

A second unit pixel region 320 is defined by sequentially arranging IR, R, Gb and B pixels on four divided regions, which are symmetrically arranged in a vertical direction and a horizontal direction, along the clockwise direction.

The third unit pixel region 330 and the second unit pixel region 320 are defined to be alternately arranged at every odd number-th row of the whole pixel region 300C.

Likewise, the second unit pixel region 332 and the third unit pixel region 330 are defined to be alternately arranged at every even number-th row of the whole pixel region 300C.

Afterwards, a 4-color image sensor including a scheme as shown in FIG. 3C is manufactured by performing a processes for forming the whole pixel region 300C, which is defined as described above.

In conclusion as shown in FIG. 3C, in case that unit pixel regions are defined in the whole pixel region 300C along a row direction and a column direction, the third unit pixel region 330 excluding IR pixel and the second unit pixel region 320 having the IR pixel instead of the Gr pixel are defined to be alternately arranged at the odd number-th rows, and the second unit pixel region 320 and the third unit pixel region 330 are defined to be alternately arranged at even number-th rows.

The image sensor having the above-described scheme may sense an infrared image and a color image of a visible ray region. Herein, the Gr pixel denotes the G pixel neighbored with the R pixel in a horizontal direction, and the Gb pixel denotes the G pixel neighbored with the B pixel in a horizontal direction. Each of the R, G, B and IR pixels includes a plurality of transistors, capacitors and photodiodes, and outputs an electrical signal corresponding to a photo signal.

By defining the arrangement of the IR pixels as shown in FIG. 3C, the IR color has a same resolution compared to a conventional 4-color image sensor and a spatial frequency of the G pixel is improved to two times compared to a conventional 4-color image sensor by defining the arrangement of the IR pixels as shown in FIG. 3. Thus, a function of a conventional DPC may be used.

In FIG. 3C, the IR pixel region is exemplarily illustrated to be arranged in a diagonal line along a right and upward direction, but the embodiment of the present invention is not limited to this.

For example, in another embodiment of the present invention, the IR pixel region may be arranged in a diagonal line along a left and upward direction. In more details, the third unit pixel region may be defined by sequentially arranging Gr, R, Gb and B pixels on four divided regions, which are symmetrically arranged in a vertical direction and a horizontal direction, in a counter clockwise direction. A second unit pixel region may be defined by sequentially arranging IR, R, Gb and B pixels on four divided regions, which are symmetrically arranged in a vertical direction and a horizontal direction, along a counter clockwise direction. That is, when the third unit pixel region and the second unit pixel region are defined, the IR pixels may be arranged in a diagonal line along the left and upward direction if corresponding pixels are defined to be arranged along from right to left.

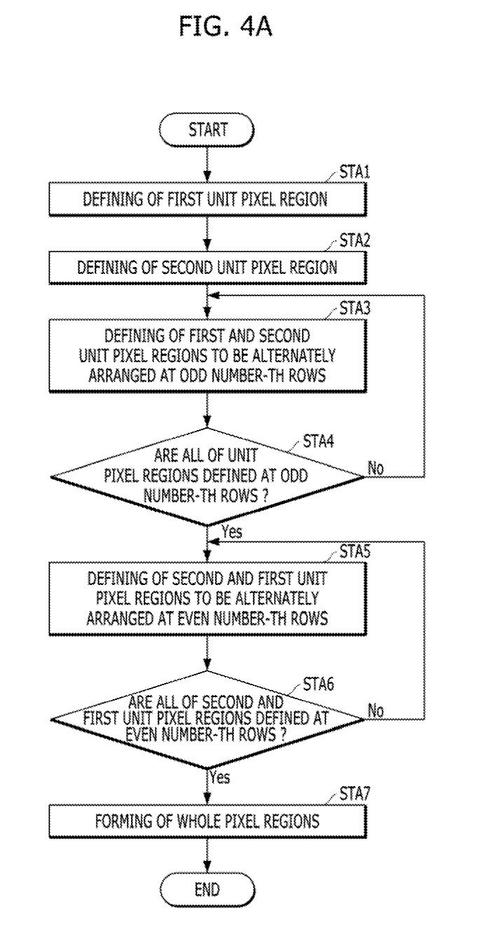

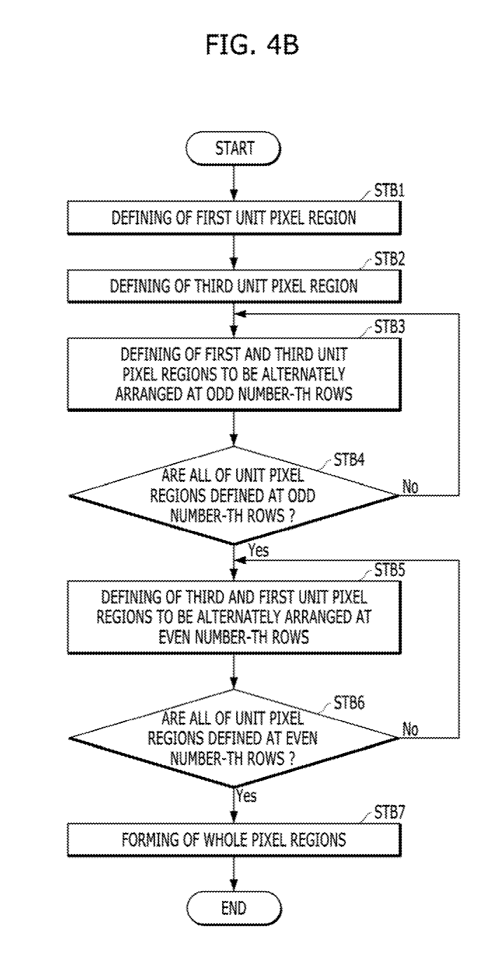

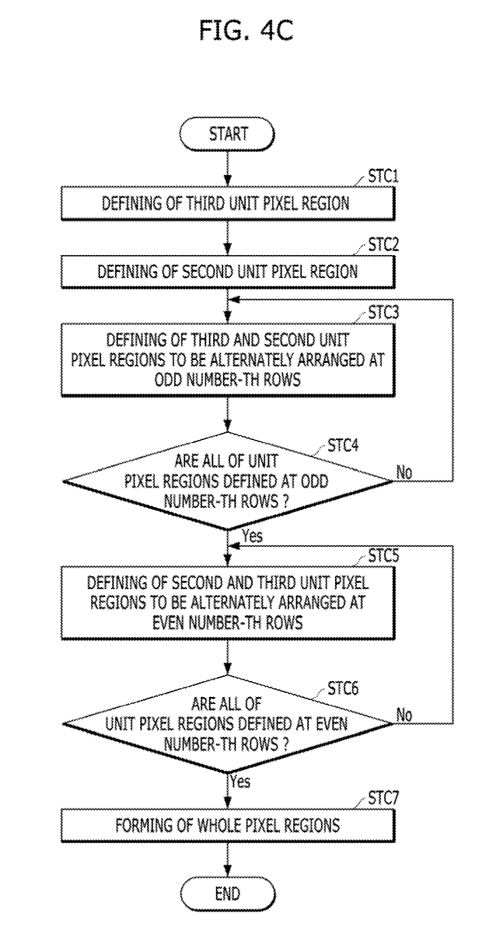

FIG. 4A is a flow chart illustrating a method for fabricating the 4-color image sensor shown in FIG. 3A in accordance with the first embodiment of the present invention.

As shown in FIG. 4A, in the step STA1, the first unit pixel region 310 is defined by sequentially arranging Gr R, IR and B pixels on four divided regions, which are symmetrically arranged in a vertical direction and a horizontal direction, along a clockwise direction.

In the step STA2, the second unit pixel region 320 is defined by sequentially arranging IR, R, Gb and B pixels on four divided regions, which are symmetrically arranged in a vertical direction and a horizontal direction, along the clockwise direction.

In the steps STA3 and STA4, the first unit pixel region 310 and the second unit pixel region 320 are defined to be alternately arranged at every odd number-th row of the whole pixel region 300A.

In the steps STA5 and STA6, the second unit pixel region 320 and the first unit pixel region 310 are defined to be alternately arranged at every even number-th row of the whole pixel region 300A.

In the step STA7, if the unit pixel regions are defined in the whole pixel regions through the steps STA1 to STA6, the 4-color image sensor is manufactured by performing a processes for forming the whole pixel region 300A, which is defined as described above.

In conclusion, in case that unit pixel regions are defined in the whole pixel region 300A along a row direction and a column direction, the IR pixel instead of the Gb pixel is defined to be arranged on an odd number-th unit pixel region, and the IR pixel instead of the Gr pixel is defined to be arranged on an even number-th unit pixel region.

FIG. 4B is a flow chart illustrating a method for fabricating a 4-color image sensor shown in FIG. 3B in accordance with a second embodiment of the present invention.

As shown in FIG. 4B, in the step STB1, a first unit pixel region 310 is defined by sequentially arranging Gr, R, IR and B pixels on four divided regions, which are symmetrically arranged in a vertical direction and a horizontal direction, along a clockwise direction.

In the step STB2, a third unit pixel region 330 is defined by sequentially arranging Gr, R, Gb and B pixels on four divided regions, which are symmetrically arranged in a vertical direction and a horizontal direction, along the clockwise direction.

In the steps STB3 and STB4, the first u nit pixel region 310 and the third unit pixel region 330 are defined to be alternately arranged at every odd number-th row of the whole pixel region 300B.

In the steps STB5 and STB6, the third unit pixel region 330 and the first unit pixel region 310 are defined to be alternately arranged at every even number-th row of the whole pixel region 300B.

In the step B7, if the unit pixel regions are defined in the whole pixel region through the steps STB1 to STB6, the 4-color image sensor is manufactured by performing a processes for forming the whole pixel region 300B, which is defined as described above.

In conclusion, in case that unit pixel regions are defined in the whole pixel region 300B along a row direction and a column direction, the IR pixel instead of the Gb pixel is arranged in an odd number-th unit pixel region, and the IR pixel is excluded and the Gr, R, Gb and B pixels are arranged at an even number-th unit pixel region.

FIG. 4C is a flow chart illustrating a method for fabricating a 4-color image sensor shown in FIG. 3C in accordance with a first embodiment of the present invention.

As shown in FIG. 4C, in the step STC1, the third unit pixel region 330 is defined by sequentially arranging Gr R, Gb and B pixels on four divided regions, which are symmetrically arranged in a vertical direction and a horizontal direction, along the clockwise direction.

In the step STC2, the second unit pixel region 320 is defined by sequentially arranging IR, R, Gb and B pixels on four divided regions, which are symmetrically arranged in a vertical direction and a horizontal direction, along the clockwise direction.

In the steps STC3 and STC4, the third unit pixel region 330 and the second unit pixel region 320 are defined to be alternately arranged at every odd number-th row of the whole pixel region 300C.

In the steps STC5 and STC6, the second unit pixel region 332 and the third unit pixel region 330 are defined to be alternately arranged at every even number-th row of the whole pixel region 300C.

In the step STC7, the 4-color image sensor manufactured by performing a processes for forming the whole pixel region 300C, which is defined as described above.

In conclusion, in case that unit pixel regions are defined in the whole pixel region 300C along a row direction and a column direction, the IR pixel region is not defined and the Gr, R, Gb and B pixels are defined in the odd number-th unit pixel region. And, the IR pixel instead of the Gr pixel is defined to be arranged in the even number-th unit pixel region.

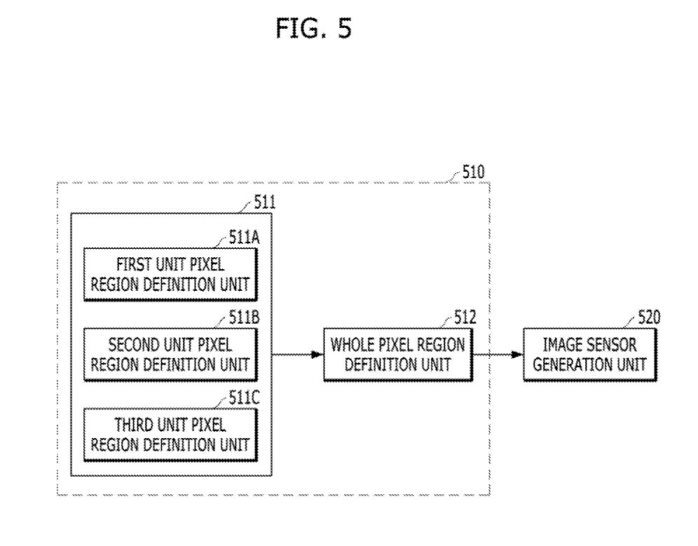

FIG. 5 is a block diagram illustrating a configuration of a 4-color image sensor in accordance with embodiments of the present invention.

Referring to FIG. 5, the 4-color image sensor includes a pixel region definition unit 510 and an image sensor generation unit 520.

The pixel region definition unit 510 includes a unit pixel region definition unit 511 and a whole pixel region definition unit 512.

The unit pixel region definition unit 511 includes a first unit pixel region definition unit 511A, a second unit pixel region definition unit 511B and a third unit pixel region definition unit 511C.

The first unit pixel region definition unit 511A defines the Gr, R, IR and B pixel regions to be arranged on four divided regions, which are symmetrically arranged in a vertical direction and a horizontal direction, along a clockwise direction.

The second unit pixel region definition unit 511B defines the IR, R, Gb and B pixel regions to be arranged on four divided regions, which are symmetrically arranged in a vertical direction and a horizontal direction, along a clockwise direction.

The third unit pixel region definition unit 511C defines the Gr, R, Gb and B pixel regions to be arranged on four divided regions, which are symmetrically arranged in a vertical direction and a horizontal direction, along a clockwise direction.

The whole region definition unit 512 defines all pixels of the whole pixel region based on two unit pixel regions among three unit pixel regions, which are defined by each of the first to third unit pixel definition units 511A to 511C.

For example, the whole pixel region definition unit 512 may define the whole pixel regions having a pixel arrangement same as the pixel arrangement of the 4-color image sensor shown in FIG. 3A based on the first unit pixel region defined by the first unit pixel region definition unit 511A and the second unit pixel region defined by the second unit pixel region definition unit 511B.

In another example, the whole pixel region definition unit 512 may define the whole pixel regions having a pixel arrangement same as the pixel arrangement of the 4-color image sensor shown in FIG. 3B based on the first unit pixel region defined by the first unit pixel region definition unit 511A and the third unit pixel region defined by the third unit pixel region definition unit 511C.

In another example, the whole pixel region definition unit 512 may define the whole pixel regions having a pixel arrangement same as the pixel arrangement of the 4-color image sensor shown in FIG. 3C based on the third unit pixel region defined by the third unit pixel region definition unit 511C and the second unit pixel region defined by the second unit pixel region definition unit 511B.

The image sensor generation unit 520 performs a forming of the image sensor having corresponding pixel scheme on the whole pixel region, which is defined as any one of the pixel arrangements of the 4-color image sensor shown in FIGS. 3A to 3C by the pixel region definition unit 510.

The 4-color image sensor in accordance with embodiments of the present invention senses G color and IR color once per one line and minimizes the degradation of the resolution of the G color and IR color by appropriately arranging IR pixel to be not concentrated to a side when the 4-color image sensor is implemented by arranging IR pixel instead of Gr or IR pixel in a 3-color image sensor scheme having Gr, R, Gb and B pixels.

Although various embodiments have been described for illustrative purposes, it will be apparent to those skilled in the art that various changes and modifications may be made without departing from the spirit and scope of the invention as defined in the following claims.

What is claimed is:

1. A 4-color image sensor, comprising:
a first unit pixel region having Gr, R, IR and B pixels on four divided regions; and
a second unit pixel region having R, R, Gb and B pixels on, four divided regions,
wherein the first unit pixel region and the second unit pixel regions are alternately arranged in a vertical direction and a horizontal direction, and the IR pixel is consecutively arranged along a diagonal line direction.

2. The 4-color image sensor of claim 1, wherein the Gr, R, IR and B pixels are sequentially arranged in the four divided regions of the first unit pixel region along a clockwise direction, and the IR, R, Gb and B pixels are sequentially arranged in the four divided regions of the second unit pixel region along the clockwise direction.

3. The 4-color image sensor of claim 1, wherein the Gr pixel and the Gb pixel are set to have a high gain value compared to other pixels.

4. The 4-color image sensor of claim 1, wherein the diagonal line direction is one of a diagonal line along a right and upward direction and a diagonal line along a left and upward direction.

5. A 4-color image sensor, comprising:
a first unit pixel region having Gr, R, IR and B pixels on four divided regions; and
a third unit pixel region having Gr, R, Gb and B pixels on four divided regions,
wherein the first unit pixel region and the third unit pixel regions are alternately arranged in a vertical direction and a horizontal direction, and IR pixel is discontinuously arranged along a diagonal line direction.

6. The 4-color image sensor of claim 5, wherein the Gr, R, IR and B pixels are sequentially arranged in the four divided regions of the first unit pixel region along a clockwise direction, and the Gr, R, Gb and B pixels are sequentially arranged in the four divided regions of the third unit pixel region along the clockwise direction.

7. A 4-color image sensor, comprising:
a third unit pixel region having Gr, R, Gb and B pixels on four divided regions; and
a second unit pixel region having IR, R, Gb and B pixels on four divided regions; and
wherein the third unit pixel region and the second unit pixel regions are alternately arranged in a vertical direction and a horizontal direction, and the IR pixel is discontinuously arranged along a diagonal line direction.

8. The 4-color image sensor of claim 7, wherein the Gr, R, Gb and B pixels are sequentially arranged in the four divided regions of the third unit pixel region along a clockwise direction, and the IR, R, Gb and B pixels are sequentially arranged in the four divided regions of the second unit pixel region along the clockwise direction.

9. The 4-color image sensor of claim 7, wherein the diagonal line direction is one of a diagonal line along a right and upward direction and a diagonal line along a left and upward direction.

10. A method for fabricating a 4-color image sensor, comprising:
defining a first unit pixel region to arrange Gr, R, IR and B pixels on four divided regions;
defining a second unit pixel region to arrange IR, R, Gb and B pixels on four divided regions;
defining the first unit pixel region and the second unit pixel region to be alternately arranged in a whole pixel region at odd number-th rows;
defining the second unit pixel region and the first unit pixel region to be alternately arranged in the whole pixel region at even number-th rows; and
forming the whole pixel region where the first unit pixel region and the second unit pixel region are defined.

11. The method for fabricating the 4-color image sensor of claim 10, wherein the IR pixel is continuously arranged in the whole pixel region along a diagonal line direction.

12. The method for fabricating the 4-color image sensor of claim 10, wherein the Gr, R, IR and B pixels are sequentially arranged in the four divided regions of the first unit pixel region along a clockwise direction, and the IR, R, Gb and B pixels are sequentially arranged in the four divided regions of the second unit pixel region along the clockwise direction.

13. A method for fabricating a 4-color image sensor, comprising:
defining a first unit pixel region to arrange Gr, R, IR and B pixels on four divided regions;
defining a third unit pixel region to arrange Gr, R, Gb and B pixels on four divided regions;
defining the first unit pixel region and the third unit pixel region to be alternately arranged in a whole pixel region at odd number-th rows;
defining the third unit pixel region and the first unit pixel region to be alternately arranged in the whole pixel region at even number-th rows; and
forming the whole pixel region where the first unit pixel region and the third unit pixel region are defined.

14. The method for fabricating the 4-color image sensor of claim 13, wherein the IR pixel is discontinuously arranged in the whole pixel region along a diagonal line direction.

15. The method for fabricating the 4-color image sensor of claim 13, wherein the Gr, R, IR and B pixels are sequentially arranged in the four divided regions of the first unit pixel region along a clockwise direction, and the Gr R, Gb and B pixels are sequentially arranged in the four divided regions of the third unit pixel region along the clockwise direction.

16. A method for fabricating a 4-color image sensor, comprising:
defining a third unit pixel region to arrange Gr, R, Gb and B pixels on four divided regions;
defining a second unit pixel region to arrange IR, R, Gb and B pixels on four divided regions;
defining the third unit pixel region and the second unit pixel region to be alternately arranged in a whole pixel region at odd number-th rows;
defining the second unit pixel region and the third unit pixel region to be alternately arranged in the whole pixel region at even number-th rows; and
forming the whole pixel region where the third unit pixel region and be second unit pixel region are defined.

17. The method for fabricating the 4-color image sensor of claim 16, wherein the IR pixel is discontinuously arranged in the whole pixel region along a diagonal line direction.

18. The method for fabricating the 4-co or image sensor of claim 16, wherein the Gr, R, Gb and B pixels are sequentially arranged in the four divided regions of the third unit pixel region along the clockwise direction, and the IR, R, Gb and B pixels are sequentially arranged in the four divided regions of the second unit pixel region along a clockwise direction.

19. The method for fabricating the 4-color image sensor of claim 17, wherein the diagonal line direction is one of a diagonal line along a right and upward direction and a diagonal line along a left and upward direction.

20. A 4-color image sensor, comprising:
a unit pixel region definition unit including
a first unit pixel region definition unit suitable for defining Gr, R, IR and B pixel regions to be arranged on four divided regions;
a second unit pixel region definition unit suitable for defining the IR, R, Gb and B pixel regions to be arranged on four divided regions; and
a third unit pixel region definition unit suitable for defining the Gr, R, Gb and B pixel regions to be arranged on four divided regions,
a whole pixel region definition unit suitable for defining two unit pixel regions among three unit pixel regions, which are defined by the first to third unit pixel definition units, to be alternately arranged in a vertical direction and a horizontal direction; and
an image sensor generation unit suitable for forming the whole pixel region, which is defined by the whole pixel region definition unit.
